(19) United States
(12) Patent Application Publication
(10) Pub. No.: US 2007/0095505 A1
(43) Pub. Date: May 3, 2007

(54) Starter controller coolant outlet flow kit

(76) Inventor: Thomas Robinson, Richardson, TX (US)

Correspondence Address: LITMAN LAW OFFICES, LTD., P.O. BOX 15035, CRYSTAL CITY STATION, ARLINGTON, VA, 22215, US

(21) Appl. No.: 11/418,136

(22) Filed: May 5, 2006

Related U.S. Application Data
(60) Provisional application No. 60/730,856, filed on Oct. 28, 2005.

(51) Int. Cl. H05K 7/20

(52) U.S. Cl. 165/80.4; 361/699; 165/119

(57) ABSTRACT

The starter controller coolant outlet flow kit includes a hollow metallic reservoir pipe having a proximal end and a distal end. A side radial hole near the proximal end is provided for a soldered connection to a header. The header is provided with a soldered end cap and a plurality of downwardly directed radial apertures. Header nipples are joined and soldered at the radial apertures. An open-mouthed reservoir bottom end piece having a rounded closure and central axial outlet hole is soldered to the proximal end of the reservoir. The central axial outlet hole is soldered to a reservoir outlet nipple. An arch-shaped strainer is lodged in the reservoir pipe over the radial hole. A threaded receiver piece is joined and soldered to the distal end of the reservoir pipe. A top threaded plug threads into the receiver piece to seal the top of the reservoir.

### CROSS-REFERENCE TO RELATED APPLICATION

This application claims the benefit of U.S. Provisional Patent Application Ser. No. 60/730,859, filed Oct. 28, 2005.

### BACKGROUND OF THE INVENTION

1. Field of the Invention

The present invention relates to cooling systems for the electronic components of large scale air-conditioning units known as “chillers”, and particularly to a starter controller coolant outlet kit therefor.

2. Description of the Related Art

Chillers are generally large scale liquid coolers for used in Heating, Ventilation and Air Conditioning (HVAC) systems for buildings, such as apartment buildings, offices, and other commercial edifices, having large amounts of volume to cool. The chillers generally have many electric motors for pumping coolant water, refrigerant, and the like.

In addition, large air blowers are usually connected as part of the chiller system. All of these motors and other electrical components of the HVAC system require careful synchronization during start up and operation. Hence solid state, i.e., semiconductor starter controllers under microprocessor control have evolved to perform electrical component startup, synchronization and control.

Generally, electric motor control is accomplished by providing very large-scale silicon controlled rectifiers (SCRs) that are gated to switch the motors on and off. These SCRs generate large amounts of heat that must be dealt with to keep the starter controller in operation without triggering an overheat fail-safe shut down.

In many designs, a portion of the heat dissipation is accomplished by mounting the SCRs on large finned or plate like heat sinks. One such design incorporates a bank of heat sinks that also includes a network of coolant pipes disposed behind the heat sinks to further dissipate the heat generated by solid-state components, such as the aforementioned SCRs.

For example, a YORK® model SSS 7L-A incorporates heat sinks backed by a closed loop flow of water and corrosive inhibitor over the heat sinks. The traditional design incorporated in the water outlet system for flow of water out of the solid-state controller housing has been a plastic type header and reservoir system. Many of the chillers employing the plastic type header and reservoir are experiencing failures due to leaks in the closed loop coolant system caused by stress and wear of the plastic components. To date, there has been no durable, metal replacement for these original equipment manufacture (OEM) components.

For example, German Patent No. 4,040,495, published July 1992, describes a one-piece hollow adaptor for connecting rigid pipes to flexible tubes, however does not describe a combination of components operable as a starter controller coolant outlet flow kit. Japanese Patent No. 8-226,729, published September 1996, appears to disclose an integrated refrigerating cycle part for air conditioning equipment, however, does not appear to describe the particular combination disclosed in the present invention. Similarly, French Patent No. 2,754,885, published April 1998, discusses separation of gas and liquid phases in a condenser that has a number of parallel tubes for use in motor vehicle air conditioning, but unlike the present invention does not disclose an outlet flow kit for coolant in a single phase.

French Patent No. 2,758,877, published July 1998, appears to discuss a reservoir integrated with a heat exchanger in a condenser for refrigeration, but unlike the present invention, does not appear to discuss a kit that could be used to-cool starter controller electronics. Similarly, French Patent No. 2,777,638, published October 1999, discusses an automobile air conditioning condenser with integrated reservoir, but unlike the present invention, does not address a starter controller coolant outlet flow kit.

None of the above inventions and patents, taken singly or in combination, describes the present invention as claimed. Thus, a starter controller coolant outlet flow kit solving the aforementioned problems is desired.

### SUMMARY OF THE INVENTION

The starter controller coolant outlet flow kit is a replacement kit for OEM components of a starter controller for improved durability and operation of a closed loop liquid cooling system for solid state components of a chiller starter. The kit includes a hollow metallic reservoir pipe having a proximal end and a distal end.

A side radial hole near the proximal end is provided for a soldered connection to a header. The header is provided with a soldered end cap and a plurality of downwardly directed radial apertures. Header nipples are joined and soldered at the radial apertures. An open-mouthed reservoir bottom end piece having a rounded closure and central axial outlet hole is soldered to the proximal end of the reservoir.

The central axial outlet hole has a reservoir outlet nipple soldered thereto. An arch-shaped strainer is lodged in the reservoir over the radial hole. A threaded receiver piece is joined and soldered to the distal end of the reservoir pipe. A top threaded plug threads into the receiver piece to seal the top of the reservoir.

These and other features of the present invention will become readily apparent upon further review of the following specification and drawings.

### BRIEF DESCRIPTION OF THE DRAWINGS

FIG. 1 is an environmental, perspective view of a starter controller coolant outlet flow kit according to the present invention installed on a solid-state controller.

FIG. 2 is a side view of the coolant outlet flow kit of the present invention.

FIG. 3A is an environmental side view showing the heat sink and water connection to the coolant outflow kit of the present invention.

FIG. 3B is an environmental rear view showing the heat sink and water connection to the coolant outflow kit of the present invention.

FIG. 3C is a diagrammatic view of a heat exchanger and pump connected to the coolant outlet flow kit of the present invention.

FIG. 4 is an exploded, perspective view of the coolant outlet flow kit of the present invention.

Similar reference characters denote corresponding features consistently throughout the attached drawings.

### DETAILED DESCRIPTION OF THE PREFERRED EMBODIMENT

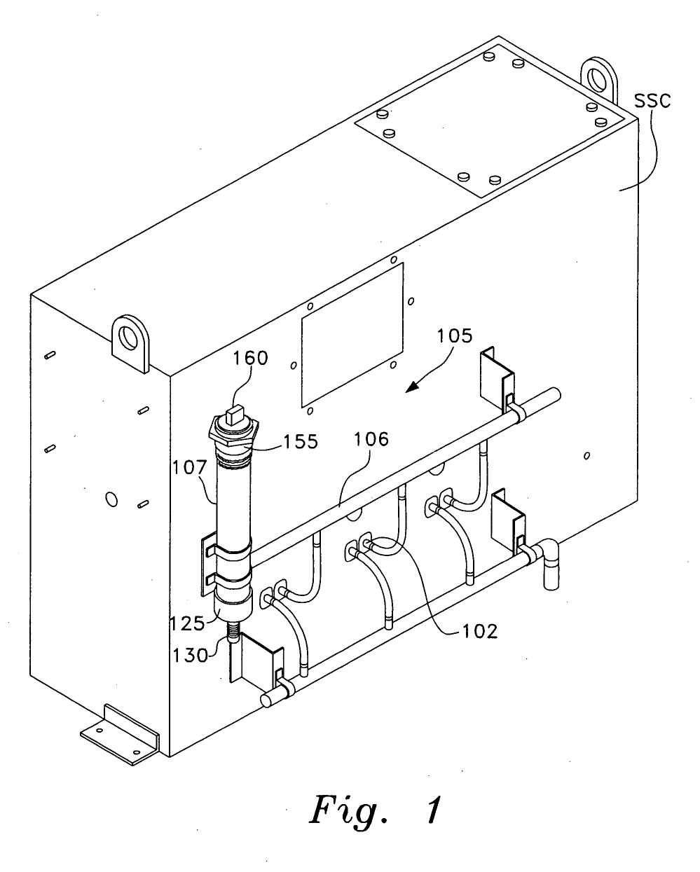

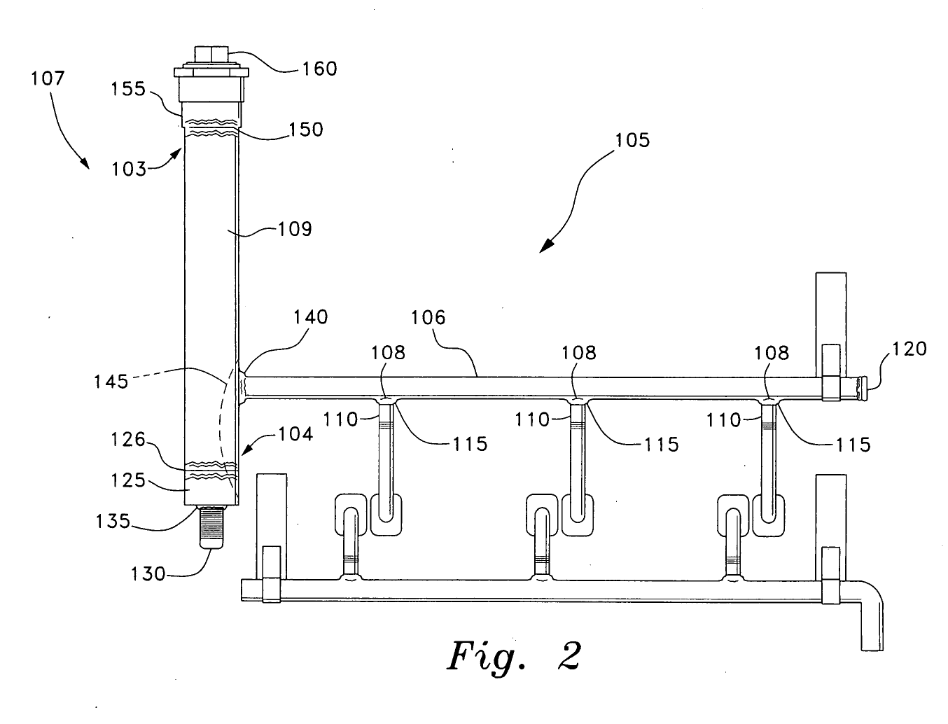

As shown in FIGS. 1 and 2, the present invention is a starter controller coolant outlet flow kit 105 that attaches to outlet flow connections 102 originating from a liquid coolant path within a solid-state controller SSC. All components of the kit 105 are preferably metallic, and suitable for being bonded to each other by soldering. Main components of the kit 105 include the reservoir 107 and the header 106. The reservoir 107 is formed from a hollow, metallic, e.g., copper, or the like, reservoir pipe 109 having a proximal end and a distal end.

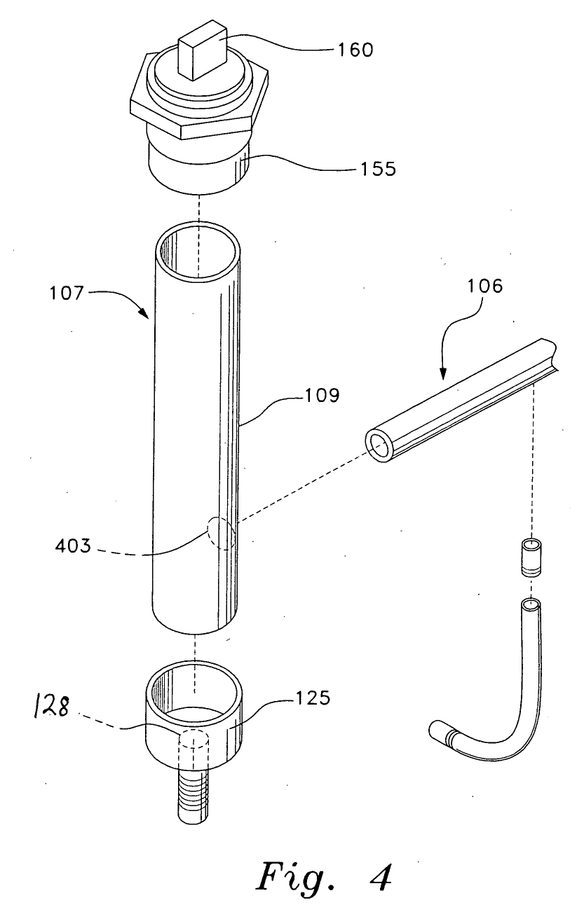

As shown in FIGS. 2 and 4, a side radial hole 403 near the proximal end is provided where the reservoir pipe 109 joins the header 106 in a reservoir-to-header soldered joint 140 at an axial opening of the hollow header 106. The header 106 is provided with a plurality of downwardly directed radial apertures 108, and an end cap 120 for sealing off a remaining axial opening at an end cap joint. The end cap joint is soldered with silvaloy compound at a minimum of approximately 1300° F.

Preferably, hollow header nipples 110 are joined and soldered at header radial aperture joints 115. An open-mouthed reservoir bottom end piece 125 having a rounded closure and central axial outlet hole 128 fits snugly over the proximal end 104 of reservoir pipe 109 and is soldered at an end piece joint 126 over the fitting to the proximal end 104 of the reservoir pipe 109.

The central axial outlet hole 128 is attached to a preferably hollow reservoir outlet nipple 130, a portion of which snugly fits inside axial outlet hole 128. The fitting is then soldered in place. A partially spherical arch-shaped strainer 145 having a plurality of small grid-shaped openings for filtration of solid impurities in a liquid fluid flow is lodged inside the metallic reservoir pipe 107 near the lower proximal end 104 so that it surrounds the radial hole 403.

A hollow, substantially cylindrical internally threaded metallic, preferably copper, receiver piece 155 is snugly fitted over the distal end 103. The receiver piece fitting is then soldered to the distal end 103 of the reservoir pipe 109 at receiver piece joint 150. A top, threaded plug 160 threads into the receiver piece 155 to seal the top of the reservoir 107. The top plug 160 may be brass, copper, or polymeric in composition.

Moreover, the aforementioned solder joints are preferably completed with a 15% silvaloy compound, or equivalent, raised to a temperature of at least approximately 1300° F. while soldering. Additionally, each of the aforementioned individual components of the starter controller coolant outlet flow kit, according to the present invention, may be scaled up or down in size to custom fit any type of starter controller.

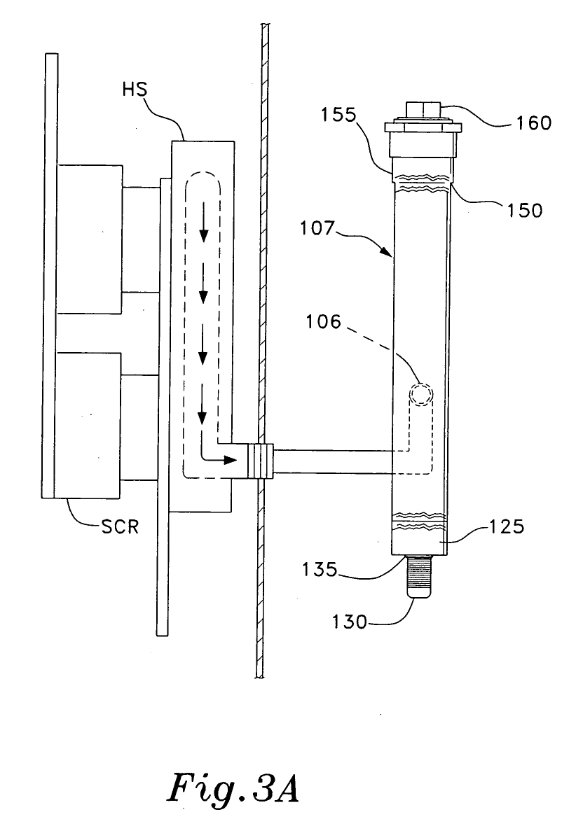

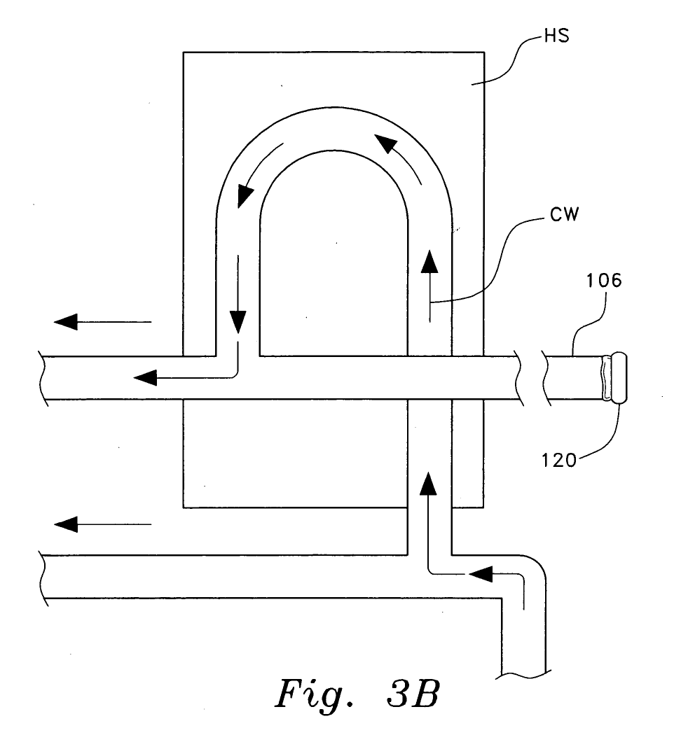

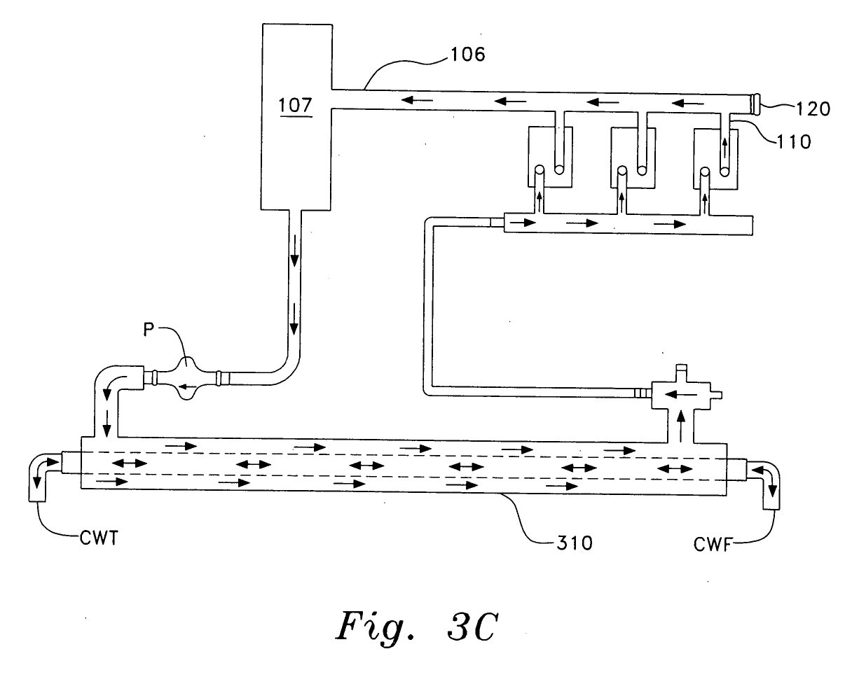

As shown in FIGS. 2 and 3A through 3C, usage of the reservoir header coolant outlet flow kit 105 is accomplished by connecting the outlet water pipe surrounding heat sink HS to the header pipe 106 through a fitting to the header aperture nipple connectors 110. The reservoir outlet nipple connector 130 is then fitted with a line that is connected to a pump P, which, in turn, cycles the coolant water through a heat exchanger 310, thus keeping the water cool enough to dissipate heat from the heat sink HS on a return flow, as shown in FIGS. 3A through 3C.

It is to be understood that the present invention is not limited to the embodiment described above, but encompasses any and all embodiments within the scope of the following claims.

I claim:

1. A starter controller coolant outlet flow kit, comprising:
a metallic reservoir pipe having a lower proximal end and an upper distal end, the pipe having a side radial hole defined therein adjacent the lower proximal end;
a metallic bottom end cap having an outlet nipple extending therefrom, the bottom end cap being soldered to the lower proximal end of the reservoir pipe;
a partially spherical arch-shaped strainer for filtration of solid impurities disposed within the reservoir pipe over the side radial hole;
a metallic receiver soldered to the upper distal end of the reservoir pipe, the receiver being internally threaded and adapted for receiving a top plug; and
an elongated header pipe extending from the side radial hole of the reservoir pipe, the header pipe being soldered to the reservoir pipe and adapted for attachment to a coolant system of an air conditioning system starter controller.

2. The starter controller coolant outlet flow kit according to claim 1, wherein the metallic reservoir pipe is made of copper.

3. The starter controller coolant outlet flow kit according to claim 1, wherein the metallic reservoir pipe is made from a copper alloy.

4. The starter controller coolant outlet flow kit according to claim 1, wherein said header pipe has a plurality of downwardly directed radial apertures defined therein and a header end cap sealing off the header axially at an end opposite said reservoir pipe, the header end cap being a soldered to the header pipe.

5. The starter controller coolant outlet flow kit according to claim 4, further comprising: hollow header nipples soldered to the downwardly directed radial apertures.

6. The starter controller coolant outlet flow kit according to claim 1, wherein said strainer has a plurality of small grid-shaped openings defined therein.

7. The starter controller coolant outlet flow kit according to claim 1, further comprising a top plug attached to said receiver, the top plug being made from copper.

8. The starter controller coolant outlet flow kit according to claim 1, further comprising a top plug attached to said receiver, the top plug being made from a copper alloy.

9. The starter controller coolant outlet flow kit according to claim 1, further comprising a top plug attached to said receiver, the top plug being made from a synthetic polymer.

10. The starter controller coolant outlet flow kit according to claim 1, wherein the pipes are soldered by a 15% silvaloy compound raised to a temperature of about 1300° F. while soldering.
